(19) United States
(12) Patent Application Publication
(10) Pub. No.: US 2023/0137157 A1
(43) Pub. Date: May 4, 2023

(54) FLIGHT VEHICLE AND CONTINUITY TEST METHOD

(71) Applicant: Fukushima Sangikyo Corporation, Fukushima (JP)

(72) Inventor: Yuichi FUKUSHIMA, Fukushima (JP)

(21) Appl. No.: 18/001,880

(22) PCT Filed: Feb. 19, 2021
(86) PCT No.: PCT/JP2021/006469

§ 371 Date: Dec. 15, 2022

(30) Foreign Application Priority Data
Jul. 13, 2020 (JP) 2020-120089

(51) Int. Cl. B64U 10/14; B64U 20/83

(52) U.S. Cl. CPC B64U 10/14; B64U 20/83; B64U 2101/26

(57) ABSTRACT

The present invention addresses the problem of providing a flight vehicle that enables safe and easy test for continuity in structures. The flight vehicle 100 according to the present invention comprises: a flight vehicle body 110; a conductive member 120 for contact with the conductor of a structure; and a movement mechanism 130 capable of moving the conductive member 120 between distal and proximal positions with respect to the flight vehicle body 100. The movement mechanism 130 may be also provided with a support rod 130 that supports the conductive member 120, and a rod movement means 130b capable of moving the support rod 130 in the distal direction.

### TECHNICAL FIELD

The present invention relates to an aerial vehicle and an electrical connectivity inspecting method. The present invention particularly relates to an aerial vehicle comprising a conductive member for contacting a conductor of a structure, and an electrical connectivity inspecting method using such an aerial vehicle.

### BACKGROUND ART

Tall structures such as steel poles of a power line, high-rise buildings, and blades of a wind turbine, etc. are equipped with measures against lightning strikes. For example, a receptor for receiving a lightning strike (metal lightning receiving unit) and a down conductor are provided to a blade of a wind turbine. Meanwhile, electrical connectivity of receptors and down conductors needs to be inspected in buildings equipped with such a measure against lightning strikes.

If, for example, an electrical connection between a receptor and ground via a down conductor is not secured on a blade of a wind turbine, lightning strike on the receptor could generate a spark to damage the wind turbine blade, etc. Thus, electrical connectivity of the receptors, etc. (including down conductors) needs to be inspected.

### SUMMARY OF INVENTION

### Technical Problem

However, it was necessary in the past to inspect electrical connectivity of a receptor, etc. on a wind turbine blade which is still attached to a hub of a wind turbine manually at a high elevation. Thus, electrical connectivity of a receptor, etc. could not be readily inspected as the inspection entails a high level of risk.

The objective of the present invention is to provide an aerial vehicle that enables safe and simple electrical connectivity inspection on a structure and an electrical connectivity inspecting method using such an aerial vehicle.

### Solution to Problem

The present invention provides the following items.

### Item 1

An aerial vehicle, comprising:

an aerial vehicle body;

a conductive member for contacting a conductor of a structure; and

a moving mechanism capable of moving the conductive member between a distal position and a proximal position of the aerial vehicle body.

### Item 2

The aerial vehicle of item 1, wherein the moving mechanism comprises:

a support rod for supporting the conductive member; and

rod moving means capable of moving the support rod to a distal direction.

### Item 3

The aerial vehicle of item 1, wherein the moving mechanism comprises:

an extendable/retractable support rod for supporting the conductive member; and

rod extending/retracting means for extending/retracting the support rod.

### Item 4

The aerial vehicle of item 3, wherein the extendable/retractable support rod comprises at least:

a first rod coupled to the conductive member; and

a second rod for protrudably and embeddably housing the first rod.

### Item 5

The aerial vehicle of any one of items 2 to 4, wherein the conductive member and the support rod are coupled with a coupling member so that a posture of the conductive member can be changed in any manner.

### Item 6

The aerial vehicle of item 5, wherein

the coupling member comprises a plurality of flexible members, and

the plurality of flexible members are disposed with a given angular interval axially about the support rod.

### Item 7

The aerial vehicle of item 5, wherein the coupling member is a universal joint.

### Item 8

The aerial vehicle of any one of items 1 to 7, wherein the aerial vehicle further comprises a rotation mechanism for rotating the conductive member.

### Item 9

The aerial vehicle of any one of items 1 to 8, wherein the conductive member comprises at least one of a metal wire netting, a polishing member, a checker plate, a metal scrubber, and a perforated board.

### Item 10

The aerial vehicle of any one of items 2 to 7, wherein the support rod or the conductive member further comprises fixing means for fixing the conductive member to the conductor.

### Item 11

The aerial vehicle of any one of items 1 to 10, wherein the moving mechanism moves a conductive member in a substantially vertical direction of the aerial vehicle body, and the distal position is a position in an upward direction of the substantially vertical direction with respect to the proximal position.

### Item 12

A method of conducting electrical connectivity inspection on the structure by using the aerial vehicle of any one of items 1 to 11, comprising:

moving the aerial vehicle to a position below a conductor of the structure while the conductive member is at the proximal position; and

contacting the conductive member with the conductor of the structure by moving the conductive member to the distal position to conduct electrical connectivity inspection.

### Item 13

The method of item 12, further comprising:

fixing the conductive member to the conductor;

detaching the conductive member from the aerial vehicle, while the conductive member is fixed to the conductor, to release the aerial vehicle from the structure; and

disengaging fixation of the conductive member to the conductor as of completion of the electrical connectivity inspection to release the conductive member from the structure.

### Item 14

The method of item 12 or 13, wherein the conductor of the structure is a receptor provided at a tip of a wind turbine blade.

### Advantageous Effects of Invention

An aerial vehicle that enables safe and simple electrical connectivity inspection on a structure and an electrical connectivity inspecting method using such an aerial vehicle can be obtained through the present invention.

### BRIEF DESCRIPTION OF DRAWINGS

FIG. 1 is a perspective view for describing aerial vehicle 100 according to Embodiment 1 of the invention. FIG. 1(a) shows the outer appearance of the aerial vehicle 100, and FIG. 1(b) shows a state in which conductive member 120 is separated from the aerial vehicle 100.

FIG. 2 is a diagram for describing the specific configuration of moving mechanism 130 of the aerial vehicle 100 shown in FIG. 1. FIG. 2(a) is a side view of the aerial vehicle 100 in FIG. 1 viewed from direction A, and FIG. 2(b) is a vertical cross-sectional view of housing 110b shown in FIG. 2(a).

FIG. 3 is a diagram for describing a method of inspecting electrical connectivity of a receptor, etc. by using the aerial vehicle 100 shown in FIG. 1. FIG. 3(a) shows ascending and descending motions of the aerial vehicle 100 in FIG. 1, and FIG. 3(b) shows an upward movement of the conductive member 120 of the aerial vehicle 100 in FIG. 1.

FIG. 4 is a diagram for describing moving mechanism 131 of aerial vehicle 101 according to Modified Example 1 of Embodiment 1. FIG. 4(a) is a side view of the aerial vehicle 101, and FIG. 4(b) is a vertical cross-sectional view of the housing 110b shown in FIG. 4(a).

FIG. 5 is a diagram for describing rotation mechanism 132d for rotating the conductive member 120 of aerial vehicle 102 according to Modified Example 2 of Embodiment 1. FIG. 5(a) is a side view of the aerial vehicle 102, and FIG. 5(b) is a vertical cross-sectional view of the housing 110b shown in FIG. 5(a).

FIG. 6 is a perspective view for describing aerial vehicle 200 according to Embodiment 2 of the invention. FIG. 6(a) shows the outer appearance of the aerial vehicle 200, and FIG. 6(b) shows the structure of coupling member 230c by separating the conductive member 120 from the aerial vehicle 200.

FIG. 7 is a diagram for describing the specific configuration of moving mechanism 230 of the aerial vehicle 200 shown in FIG. 6. FIG. 7(a) is a side view of the aerial vehicle 200 in FIG. 6 viewed from direction A, and FIG. 7(b) is a vertical cross-sectional view of the housing 110b shown in FIG. 7(a).

FIG. 8A is a diagram for describing a method of inspecting electrical connectivity of a receptor, etc. by using aerial vehicle 300 according to Embodiment 3 of the invention. FIG. 8A(a) shows ascending and descending motions of the aerial vehicle 300, and FIG. 8A(b) shows an operation of fixing the conductive member 120 of the aerial vehicle 300 to a receptor.

FIG. 8B is a diagram for describing a method of inspecting electrical connectivity of a receptor, etc. by using the aerial vehicle 300 according to Embodiment 3 of the invention. FIG. 8B(a) shows an operation of releasing the aerial vehicle 300 from a wind turbine blade while a conductive member is still fixed to a receptor, and FIG. 8B(b) shows an operation of disengaging fixation of a conductive member to a receptor to release the conductive member from a wind turbine blade after electrical connectivity inspection.

### DESCRIPTION OF EMBODIMENTS

The present invention is described hereinafter. The terms used herein should be understood as being used in the meaning that is commonly used in the art, unless specifically noted otherwise. Thus, unless defined otherwise, all terminologies and scientific technical terms that are used herein have the same meaning as the general understanding of those skilled in the art to which the present invention pertains. In case of a contradiction, the present specification (including the definitions) takes precedence.

As used herein, “about” refers to a range of ±10% from the number that is described subsequent to “about”.

The problem to be solved by the present invention is to provide an aerial vehicle that enables safe and simple electrical connectivity inspection on a structure. The problem to be solved described above was solved by providing An aerial vehicle, comprising:

an aerial vehicle body;

a conductive member for contacting a conductor of a structure; and

a moving mechanism capable of moving the conductive member between a distal position and a proximal position of the aerial vehicle body.

Specifically, the conductive member for contacting a conductor of a structure can move between the distal position and the proximal position of the aerial vehicle body in view of the moving mechanism in the aerial vehicle of the invention. Thus, electrical connectivity can be inspected by moving the aerial vehicle to a position below the conductor of the structure while the conductive member is at the proximal position and subsequently moving the conductive member from the proximal position to the distal position to contact the conductive member with the conductor of the structure.

For this reason, a conductive member of an aerial vehicle and a conductor of a structure can be contacted at least by an operation of moving the conductive member from the proximal position to the distal position of the aerial vehicle body, where there is hardly any risk of the aerial vehicle body colliding with the structure, so that the conductive member of the aerial vehicle and the conductor of the structure can be contacted safely and easily.

Thus, if the aerial vehicle of the invention has a conductive member for contacting a conductor of a structure and a moving mechanism capable of moving the conductive member between a distal position and a proximal position of an aerial vehicle body, the specific configuration of the conductive member and the moving mechanism and other configurations in the aerial vehicle are not particularly limited and can have any configuration.

### Aerial Vehicle Body

An aerial vehicle body can be of any form. For example, an aerial vehicle body may be a helicopter or a multicopter such as a drone. An aerial vehicle body may be a manned or unmanned aerial vehicle. In a preferred embodiment, an aerial vehicle body is an unmanned aerial vehicle such as a remotely controllable drone. Electrical connectivity can be safely inspected by configuring an aerial vehicle as an unmanned aerial vehicle.

### Conductive Member

As long as a conductive member is a member having conductivity for contacting a conductor of a structure, other parts of the member can have any configuration.

For example, the material of a conductive member is not limited to metal, as long as the material has conductivity. The material may be carbon or plastic. Furthermore, a specific member comprises at least one of metal wire netting, checker plate, acicular metal (metal scrubber or metal brush), conductive rubber, conductive sponge, conductive wire (electric wire, conductive fiber, or conductive spring), conductive grease, conductive oil, polishing member, and perforated board.

A conductive member can have any shape or size in accordance with the shape or size of a conductor of a structure to be contacted. For example, the shape of a surface to be contacted with a conductor of a structure of a conductive member may be substantially polygonal (triangular, quadrangular, pentagonal, etc.) or substantially circular (circular, oval, etc.). While a conductive member is preferably large from the viewpoint of increasing the area of contact with a conductor of a structure, a large area would be heavier and is affected by wind, so that flight would be unstable. Thus, the area can be determined while considering the balance thereof. In an embodiment where a conductor of a structure is for example a receptor of a wind turbine blade, the size of the surface to be contacted with the receptor of a conductive member is about 70 cm² to about 2500 cm². In one embodiment, the conductive member is substantially circular with an area of about 700 cm² (diameter of about 30 cm). However, the present invention is not limited thereof.

A conductive member may comprise fixing means for fixation to a conductor of a structure. Fixing means can have any configuration. For example, fixing means may be a magnetic force generating mechanism that causes fixation to a conductor by a magnetic force, a conductive adhesive tape, etc., or fixation by adhesion through air suction means.

### Moving Mechanism

A moving mechanism can have any form, as long as it is capable of moving a conductive member between a distal position and a proximal position of an aerial vehicle body.

For example, a moving mechanism may comprise a support rod for supporting a conductive member and rod moving means capable of moving the support rod to a distal direction. Alternatively, a moving mechanism may comprise an extendable/retractable support rod for supporting a conductive member and rod extending/retracting means for extending/retracting the support rod. In this regard, the extendable/retractable support rod may comprise at least a first rod coupled to a conductive member and a second rod for protrudably and embeddably housing the first rod. Specifically, a moving mechanism may be configured so that a support rod extends by a first rod protruding out with respect to a second rod, and the support rod contracts by the first rod being embedded with respect to the second rod. The distance of movement between a distal position and a proximal position of a conductive member due to a moving mechanism can be any distance. For example, the distance of movement between a distal position and a proximal position is about 30 cm to about 150 cm. The direction of movement of a conductive member due to a moving mechanism can be any direction. For example, the direction of movement of a conductive member may be in a substantially vertical direction or a substantially horizontal direction of an aerial vehicle body. Preferably, a moving mechanism moves a conductive member in a substantially vertical direction of an aerial vehicle body. Since an aerial vehicle such as a drone can more readily move in a substantially vertical direction relative to a substantially horizontal direction, a conductive member can contact a conductor of a structure more readily if a moving mechanism can move the conductive member in a substantially vertical direction of an aerial vehicle body. When a moving mechanism moves a conductive member in a substantially vertical direction of an aerial vehicle body, it is possible to avoid the aerial vehicle body from colliding with a structure even if the aerial vehicle body is shaken in a substantially horizontal direction by a side wind.

When a moving mechanism moves a conductive member in a substantially vertical direction of an aerial vehicle body, a distal position may be a position in an upward direction or downward direction of the substantially vertical direction with respect to a proximal position. When an aerial vehicle body is remotely controlled, etc., it is easier for the visual recognition of an operator to have the aerial vehicle body approach a structure from below as a method of having the aerial vehicle body approach a conductor of the structure. In such a case, it is preferable that the moving mechanism moves the conductive member in a substantially vertical direction of the aerial vehicle body, and the distal position is a position in an upward direction of the substantially vertical direction with respect to the proximal position. However, the present invention is not limited thereto.

A support rod may further comprise fixing means for fixing a conductive member to a conductor. Fixing means can have any configuration. Fixing means may be, for example, a clamp comprising a linking mechanism, or fixation by adhesion through air suction means.

A support rod can also be detachable to an aerial vehicle. This is configured so that detachment/attachment from/to an aerial vehicle can be operated based on a wireless or wired instruction signal.

### Other Configurations

Furthermore, the connecting structure between a conductive member and a support rod can have any form. For example, a conductive member and a support rod may be coupled with a coupling member so that a posture of the conductive member with respect to the support rod (rotation direction or rotation angle with respect to the support rod) is fixed, or a conductive member and a support rod may be coupled with a coupling member so that a posture of the conductive member with respect to the support rod (rotation direction or rotation angle with respect to the support rod) can be changed in any manner.

A coupling member for coupling a conductive member and a support rod so that a posture of the conductive member with respect to the support rod can be changed in any manner may be, for example, a universal joint such as a ball joint, or may comprise a plurality of flexible members, which are disposed with a given angular interval axially about the support rod. In this regard, the flexible members can have any form. For example, flexible members may be a spring member such as a leaf spring or coil spring, an elastic wire (made of metal, resin, etc.), rubber support column or air tube, electric or air cylinder, sponge, support column comprising a parallel link mechanism, etc.

A coupling member can have any number of flexible members greater than one, such as two, three, or four or more. The orientation of the posture can be changed in various directions by increasing the number of flexible members. Flexible members can be disposed axially about a support rod at any angular interval. In a preferred embodiment, the angles at which a plurality of flexible members are disposed axially about a support rod are equal. By equally disposing a plurality of flexible members axially about a support rod in this manner, the posture of a conductive member can be changed nearly equally in directions in accordance with the orientation of the angle of force, regardless of the orientation of the angle of force applied to a conductive member. As a result, when moving a conductive member from below to above so that the conductive member abuts a wind turbine blade by moving a support rod, the conductive member can maintain a state of abutting the wind turbine blade by changing a posture of the conductive member in a direction in accordance with the orientation of a force, even when an aerial vehicle body moves sideways, etc. from being subjected to a force such as a side wind. In one embodiment, there are four flexible members each disposed at an interval of about 90° axially about a support rod. However, the present invention is not limited thereto. Adjacent flexible members may be disposed at different angles from one another. In a preferred embodiment, a configuration wherein a rotation (displacement) to any direction to which a force is applied can be readily achieved, much like a configuration with a ball joint or a plurality of flexible members disposed at a given angular interval axially about a support rod is employed. Furthermore, a force restoring the original posture can be exerted, even if the posture of a conductive member has changed due to application of an external force, by constructing a plurality of flexible members with an elastic wire or spring member. As a result, the posture of a conductive member can be stably maintained in a more efficient manner than a universal joint such as a ball joint.

Furthermore, an aerial vehicle may comprise a rotation mechanism for rotating a conductive member.

In this regard, the specific configuration of a rotation mechanism can be any configuration. For example, a rotation mechanism may be a structure, which can house a rotation shaft rotatably inside a support rod, supports a conductive member at one end of the rotation shaft housed in the support rod, and is connected to a rotation axis of a motor at the other end of a rotation shaft, or may be a rod rotation means for rotating the support rod, which rotatably retains rod moving means for causing ascent and descent of the support rod and has a built-in motor for rotating the support rod by the entire rod moving means, or may be a structure with a rotation mechanism provided to a coupling member for coupling the support rod and the conductive member, or may be a structure comprising a rotation mechanism in the conductive member itself. Insulating coating, waste, rust, etc. adhering to the surface of a conductor (receptor) can be removed by contacting the rotated conductive member with the conductor (receptor). The rotation speed, etc. of a conductive member can be appropriately adjusted in accordance with the material of the conductive member or status of an object to be removed.

The problem to be solved by the present invention is to provide a method that enables safe and simple electrical connectivity inspection on a conductor of a structure. The problem to be solved described above was solved by providing:

A method of conducting electrical connectivity inspection on a structure by using the aerial vehicle described above, comprising:

moving the aerial vehicle to a position below a conductor of the structure while the conductive member is at a proximal position; and

contacting the conductive member with a conductor of the structure by moving the conductive member to a distal position to conduct electrical connectivity inspection.

Furthermore, a structure and a conductor thereof in the present invention are not particularly limited and can have any configuration. For example, a structure is a tall structure such as a steel pole of a power line, high-rise building, or a wind turbine. A conductor of a structure is, for example, a lightning rod provided at the top end of a steel pole of a power line or on the roof of a high-rise building, and particularly preferably a receptor provided at the tip of a wind turbine blade of a wind turbine.

However, the following Embodiments 1 and 2 disclose moving mechanisms comprising a support rod for supporting a conductive member and rod moving means capable of moving the support rod to a distal direction. Embodiment 1 discloses those with the posture of a conductive member fixed with respect to a support rod.

Instead of the moving mechanism in Embodiment 1, Modified Example 1 of Embodiment 1 discloses a moving mechanism comprising an extendable/retractable support rod for supporting a conductive member and rod extending/retracting means for extending/retracting a support rod.

Modified Example 2 of Embodiment 1 discloses an aerial vehicle comprising a rotation mechanism for rotating a conductive member, in addition to the configuration of Embodiment 1. In particular, Modified Example 2 of Embodiment 1 discloses a rotation mechanism, which supports a conductive member at one end of a rotation shaft and is connected to a rotation axis of a motor at the other end of the rotation shaft.

Instead of the configuration of Embodiment 1 wherein the posture of a conductive member with respect to a support rod is fixed, Embodiment 2 discloses a configuration wherein the posture of a conductive member with respect to a support rod can be changed in any manner. In particular, Embodiment 2 discloses a configuration comprising a plurality of flexible members as a coupling member, which couples a conductive member to a support rod in a manner that the posture thereof can be changed in any manner.

The embodiments of the invention are described hereinafter with reference to the drawings.

### Embodiment 1

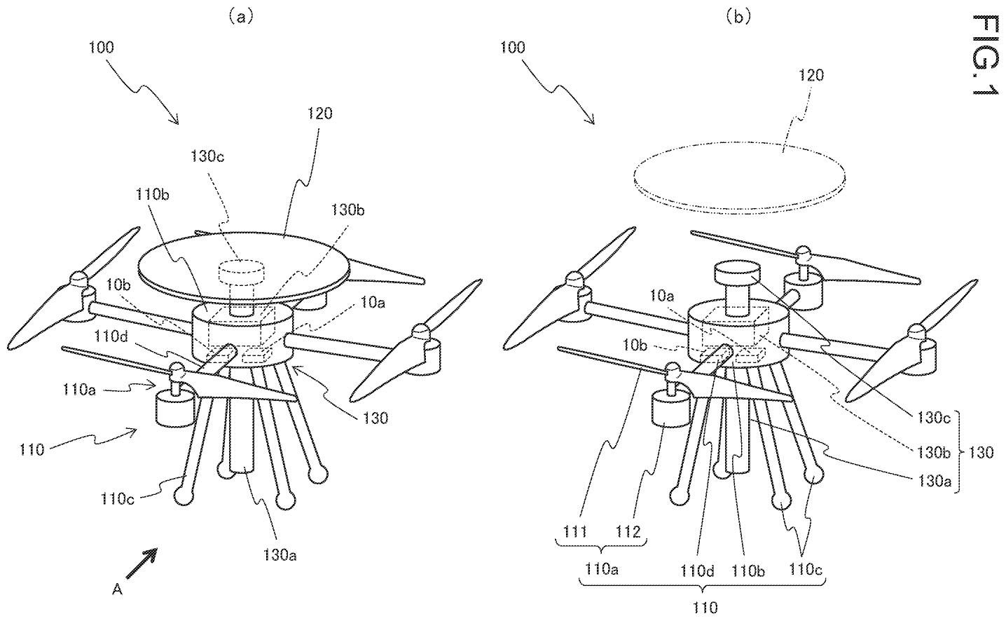

FIG. 1 is a perspective view for describing aerial vehicle 100 according to Embodiment 1 of the invention. FIG. 1(a) shows the outer appearance of the aerial vehicle 100, and FIG. 1(b) shows a state in which conductive member 120 is separated from the aerial vehicle 100.

As shown in FIG. 1(a), the aerial vehicle 100 of Embodiment 1 comprises an aerial vehicle body 110; a conductive member 120, which is a tentacle, for contacting a conductor of a structure; and a moving mechanism 130 capable of moving the conductive member 120 between a distal position and a proximal position of the aerial vehicle body 110.

### Aerial Vehicle Body 110

As shown in FIG. 1(b), the aerial vehicle body 110 is an airframe having a housing 110b, four thrust generation units 110a, four support arms 110d for supporting the four thrust generation units 110a to the housing 110b, and legs 110c attached to the housing 110b, wherein each thrust generation unit 110a has a propeller 111 and a driving motor 112. The base portion of each of the support arms 110d is fixed to the housing 110b. The driving motors 112 are attached to the tip of the respective support arms 110d, and the propellers 111 are attached to a rotation axis of the respective driving motors 112.

The housing 110b is equipped with a controller 10a and a battery 10b. The battery 10b is a power source for driving the driving motor 112 as well as a power source for a driving unit (not shown) of the moving mechanism 130. The controller 10a comprises a wireless communication unit and is a control unit for controlling flight of the aerial vehicle 100 by receiving an operation signal from a wireless remote controller and controlling the number of rotations of the four driving motors 112. The control unit also controls the driving unit (not shown) of the moving mechanism 130 to control the movement of the conductive member 120.

The embodiment shown in the diagram is described as comprising four thrust generation units and support arms, but the present invention is not limited thereto. The aerial vehicle body may have any number of thrust generation units and support arms, such as four or less (e.g., 2, etc.) or 5 or more (e.g., 8, etc.).

### Conductive Member 120

The conductive member 120 is electrically connected to a measurement device on the ground through a measurement cable (not shown). In this regard, the conductive member is comprised of metal wire netting for achieving a light weight. However, the conductive member 120 is not limited to those comprised of metal wire netting, and may be comprised of a checker plate, a metal scrubber, a perforated board, or other metal member.

### Moving Mechanism 130

As shown in FIG. 1(b), the moving mechanism 130 is built into the housing 110b of the aerial vehicle body 110 and has a support rod 130a for supporting the conductive member 120, and rod moving means 130b capable of moving the support rod 130a to a distal direction (upward direction of the housing 110b). The conductive member 120 and the support rod 130a are coupled with a coupling member 130c so that the posture of the conductive member 120 with respect to the support rod 130a is fixed in the moving mechanism 130. The coupling member 130c is a metal tubular member mated with the tip of the support rod 130a. A metal wire netting member is fixed to the top surface of the tubular member as the conductive member 120 by a fastening screw, brazing, welding, adhesive, etc. The coupling member 130c does not need to be a metal tubular member. As long as the conductive member 120 can be coupled to the support rod 130a, a resin member may be used, or a solid member may be used instead of a tubular member.

The moving mechanism 130 is described hereinafter in detail.

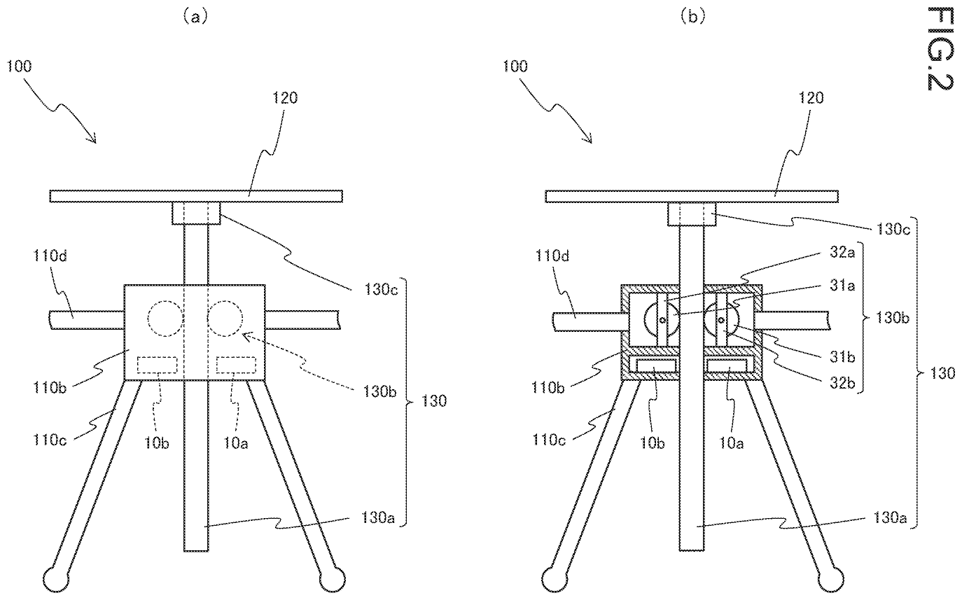

FIG. 2 is a diagram for describing the specific configuration of the moving mechanism 130 of the aerial vehicle 100 shown in FIG. 1. FIG. 2(a) is a side view of the aerial vehicle 100 in FIG. 1 viewed from direction A, and FIG. 2(b) is a vertical cross-sectional view of the housing 110b shown in FIG. 2(a) and shows the specific configuration of the rod moving means 130b housed inside the housing 110b. In FIG. 2, the propeller 111, the driving motor 112, and the near side support arm 110d are omitted in FIG. 2 to simplify the drawing.

The support rod 130a of the moving mechanism 130 is attached, to the housing 110b, slidably in a substantially vertical direction of the aerial vehicle body 110 and penetrates through the housing 110b. The rod moving means 130b of the moving mechanism 130 has a pair of rollers 31a and 31b and respective roller bearings 32a and 32b.

In this regard, the pair of rollers 31a and 31b are disposed within the housing 110b to oppose each other while flanking the support rod 130a. The rollers 31a and 31b are rotatably supported by the respective roller bearings 32a and 32b attached to the inside of the housing 110b.

The rod moving means 130b is configured so that the support rod 130a flanked by the rollers 31a and 31b moves up and down along a substantially vertical direction by rotating the pair of rollers 31a and 31b in one direction or the reverse direction. In this regard, driving means of the rollers 31a and 31b may be a motor provided external to the rollers 31a and 31b, but driving means of the rollers 31a and 31b are preferably a motor built into the rollers 31a and 31b from the viewpoint of arrangement space. The motors that are driving means of the rollers 31a and 31b are configured to be supplied with power from the battery 10b and controlled by the controller 10a.

The rod moving means 130b may use a pinion (round gear) instead of the pair of rollers 31a and 31b. In such a case, it is necessary to install a rack (with teeth engaging the teeth of the pinion formed on an elongated and flat board member) that engages with the pinion on the support rod 130a.

As the constituent material of the housing 110b, support arm 110d, leg 110c, and propeller 111 constituting the aerial vehicle body 110, the support rod 130a and coupling member 130c, and the rollers 31a and 31b and roller bearings 32a and 32b constituting the rod moving means 130b, a metal material such as steel, aluminum, stainless steel, or titanium may be used, or a hard resin material such as PVC (polyvinyl chloride), PS (polystyrene), ABS (acrylonitrile butadiene styrene), PMMA (polymethylmethacrylate), etc. may be used, or a metal material may be used for some members, and resin material for some other members.

A method of inspecting electrical connectivity of a receptor of a wind turbine blade, etc. by using the aerial vehicle 100 with such a configuration is now described.

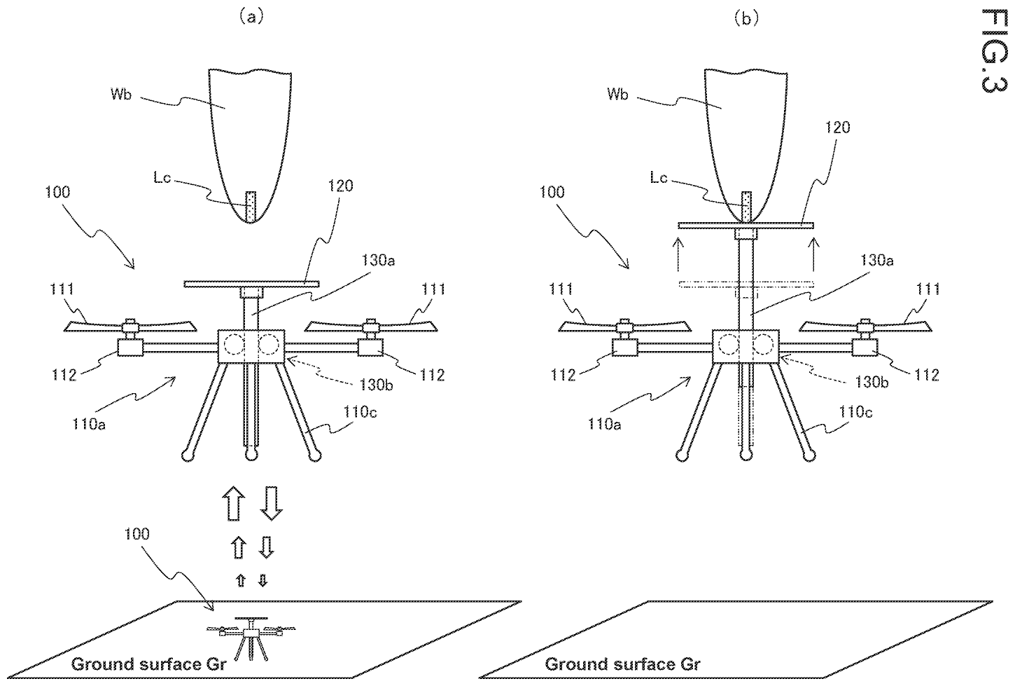

FIG. 3 is a diagram for describing a method of inspecting electrical connectivity of a receptor, etc. by using the aerial vehicle 100 shown in FIG. 1. FIG. 3(a) shows ascending and descending motions of the aerial vehicle 100 in FIG. 1, and FIG. 3(b) shows an upward movement of the conductive member 120 of the aerial vehicle 100 in FIG. 1.

A method of conducting electrical connectivity inspection on a structure such as a wind turbine blade of a wind turbine by using the aerial vehicle 100 shown in FIG. 1 comprises at least the following first step and second step.

### First Step

The first step is a step for moving the aerial vehicle 100 to a position below a conductor of a structure while maintaining the conductive member 120 at a proximal position with respect to the aerial vehicle body 110.

Specifically, a conductor of a structure is a receptor Lc of a wind turbine blade Wb, and the aerial vehicle 100 is operated with a wireless remote controller. The controller 10a of the aerial vehicle 100 controls the thrust (number of rotations of the driving motor 112) at the four thrust generation units 110a in accordance with an operation signal from the wireless remote controller (not shown), and controls the ascent/descent of the support rod 130a using the pair of rollers 31a and 31b of the rod moving means 130b in accordance with an operation signal, whereby flight of the aerial vehicle 100 and movement of the conductive member 120 are controlled as intended by an operator.

In the first step, the aerial vehicle 100 leaves ground surface Gr while stably maintaining the conductive member 120 at a position closest to the housing 110b of the aerial vehicle 100 (proximal position with respect to the aerial vehicle body 110) by an operation of an operator, and flies to a position in the vicinity of the lower side of the receptor Lc, which is positioned at the bottom end of the wind turbine blade Wb (see FIG. 3(a)). Preferably, the aerial vehicle 100 is floated at a position in the vicinity of the lower side (hovering).

In this regard, the proximal position of a conductive member is a position of the conductive member 120 where the distance between a receptor contact surface of the conductive member 120 and the top surface of the housing 110b is about 0 cm to about 70 cm in the aerial vehicle 100. The position in the vicinity of the lower side of the receptor Lc is a position of the aerial vehicle 100 where the distance between the receptor contact surface of the conductive member 120 in the proximal position and the bottom end of the receptor Lc is about 150 cm or less.

### Second Step

The second step is a step for contacting the conductive member 120 with a conductor of a structure by moving the conductive member 120 to a distal position with respect to the aerial vehicle body 110 to conduct electrical connectivity inspection.

Specifically, in the second step, the conductive member 120 is moved to the distal position with respect to the aerial vehicle 110 from the proximal position with respect to the aerial vehicle body 110 while the aerial vehicle 100 is floated at a position in the vicinity of the lower side of the receptor Lc (see FIG. 3(b)).

In this regard, the distal position is a position of the conductive member 120 where the distance between the bottom surface of the conductive member and the top surface of the housing 110b is about 30 cm to about 150 cm.

Thus, in the aerial vehicle 100 floating at a position in the vicinity of the lower side of the receptor Lc, the conductive member 120 abuts the receptor Lc of the wind turbine blade Wb while moving from the proximal position to the distal position to electrically connect the conductive member 120 of the aerial vehicle 100 with the receptor Lc of the wind turbine blade Wb, whereby the receptor Lc of the wind turbine blade Wb is connected to a measurement device on the ground via the conductive member 120 of the aerial vehicle 100 and measurement cable (not shown), and the quality of electrical connection via a down conductor between the receptor and the ground is determined in the measurement device on the ground.

When moving the conductive member 120 from the proximal position with respect to the aerial vehicle body 110 to the distal position with respect to the aerial vehicle body 110 in the second step, the aerial vehicle 100 may be elevated towards the receptor Lc instead of maintaining the aerial vehicle 100 in a floated state at a position in the vicinity of the lower side of the receptor Lc. After inspecting electrical connectivity by contacting the conductive member 120 with the receptor Lc, the aerial vehicle 100 is descended and landed on the ground surface Gr while the conductive member 120 is returned to the proximal position with respect to the aerial vehicle body 110 and the aerial vehicle 100 is stabilized (see FIG. 3(a)).

Since the aerial vehicle 100 in Embodiment 1 comprises the aerial vehicle body 110, the conductive member 120 for contacting a conductor of a structure, and the moving mechanism 130 capable of moving the conductive member 120 between a distal position and a proximal position of the aerial vehicle body 110 as described above, manual labor at a high elevation is not required. Thus, electrical connectivity can be inspected safely. Even if the aerial vehicle body 110 is shaken due to an effect of a side wind etc., the possibility of collision of the aerial vehicle body 110 with the structure (wind turbine blade) Wb can be averted by configuring the conductive member 120 to be contacted with the receptor Lc while the conductive member 120 is disposed at a distal position away from the aerial vehicle body by the moving mechanism. For this reason, the aerial vehicle 100 of the invention enables safe and simple electrical connectivity inspection on the conductor Lc of the wind turbine blade Wb.

The embodiment shown in FIG. 3 describes a case where the aerial vehicle 100 is elevated from below the receptor Lc to contact the conductive member 120 with the receptor Lc, but the present invention is not limited thereto. The aerial vehicle 100 may be descended from above the receptor Lc to contact the conductive member 120 with the receptor Lc, or the aerial vehicle 100 may be moved substantially horizontally from the side of the receptor Lc to contact the conductive member 120 with the receptor Lc. In a preferred embodiment, the aerial vehicle 100 is elevated from below the receptor Lc to contact the conductive member 120 with the receptor Lc. With such a configuration, the risk of collision with the wind turbine blade Wb can be reduced even if the aerial vehicle 100 is shaken due to a side wind, etc. Since an aerial vehicle such as a drone or helicopter can be maintained more stably when the aerial vehicle 100 is moved up or down rather than substantially horizontally in view of the mechanism thereof, the aerial vehicle 100 can be contacted with the receptor Lc more stably when moved up and down rather than substantially horizontally.

The moving mechanism 130 in the aerial vehicle 100 of Embodiment 1 comprises the support rod 130a for supporting the conductive member 120 and the rod moving means 130b capable of moving the support rod 130a in a distal direction, but the specific configuration of the moving mechanism 130 is not limited to the configuration of Embodiment 1. The support rod itself may have an extendable/retractable structure. The aerial vehicle 101 comprising a moving mechanism 131 with such a configuration is described hereinafter as Modified Example 1 of Embodiment 1.

### Modified Example 1 of Embodiment 1

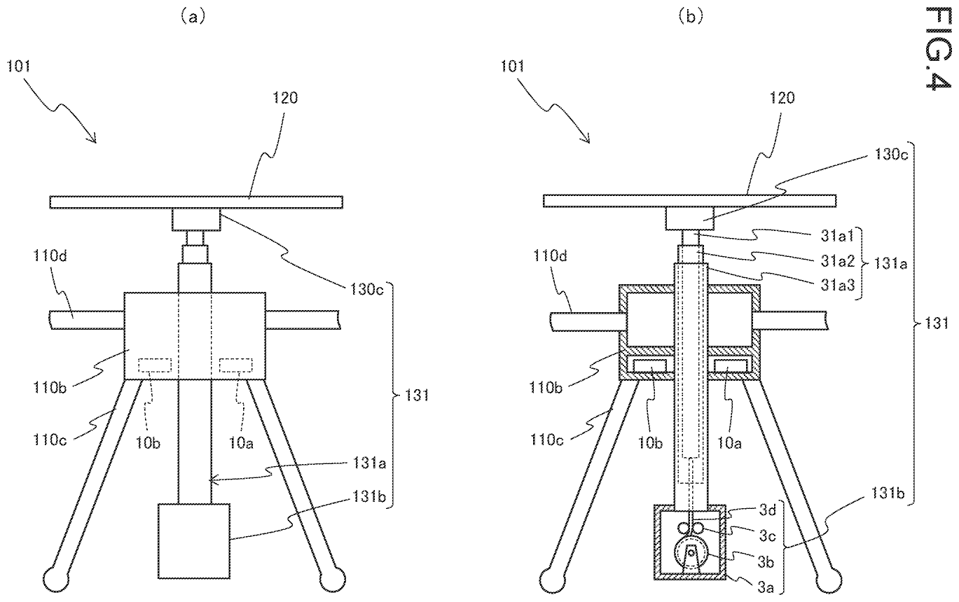

FIG. 4 is a diagram for describing the moving mechanism 131 of an aerial vehicle 101 according to Modified Example 1 of Embodiment 1. FIG. 4(a) is a side view of the aerial vehicle 101, and FIG. 4(b) is a vertical cross-sectional view of the housing 110b shown in FIG. 4(a). Specific configurations of the support rod 131a and the rod extending/retracting means 131b attached thereto are shown. The propeller 111, the driving motor 112, and the near side support arm 110d are omitted in FIG. 4, just like FIG. 2, to simplify the drawing.

The aerial vehicle 101 of Modified Example 1 of Embodiment 1 comprises the moving mechanism 131, which has a different configuration from the moving mechanism 130 in Embodiment 1. The moving mechanism 131 comprises an extendable/retractable support rod 131a in place of the support rod 130a in the moving mechanism 130, and rod extending/retracting means 131b for extending/retracting the support rod 131a in place of the rod moving means 130b for moving the support rod 130a.

Thus, other configurations in the aerial vehicle 101 in Embodiment 1, i.e., configurations other than the support rod 131a and the rod extending/retracting means 131b, are identical to those in the aerial vehicle 100 of Embodiment 1.

In this regard, the extendable/retractable support rod 131a comprises a first rod 31a1 coupled to the conductive member 120, a second rod 31a2 for protrudably and embeddably housing the first rod 31a1, and a third rod 31a3 for protrudably and embeddably housing the second rod 31a2. The first rod 31a1 is comprised of a stick-like member, and the second rod 31a2 and the third rod 31a3 are comprised of a tubular member. The metal material or hard resin material disclosed as a constituent material of the aerial vehicle 100 in Embodiment 1 can be used as the material of a stick-like member and tubular member.

The rod extending/retracting means 131b has a housing 3a, a wire member 3d, a driving roller 3b, and a guide roller 3c. The material of these members may be the metal material or resin material described above. However, the wire member 3d is flexible to the extent that the wire member can be reeled in by the main roller 3b and is rigid to the extent that the conductive member 120 can be pushed up with the first rod 31a1 and the second rod 31a2. A motor is built into the driving roller 3b. However, a motor for rotating the driving roller 3b may be provided externally instead of being built into the driving roller 3b. The motor is operated with the battery 10b and controlled by the controller 10a.

In this regard, the housing 3a of the rod extending/retracting means 131b is attached to the bottom end of the third rod 31a3, and the driving roller 3b and the guide roller 3c are disposed inside the housing 3a. The wire member 3d is wrapped onto the driving roller 3b, and the tip of the wire member 3d is coupled to the bottom end of the first rod 31a1. The guide roller 3c is disposed in the vicinity of the driving roller 3b to guide the wire member 3d so that the wire member 3d reeled out from the driving roller 3b extends along a vertical direction.

In the support rod 131a with such a configuration, the first rod 31a1 is pushed by the wire member 3d and protrudes out from within the second rod 31a2 when the wire member 3d is reeled out by a rotation of the driving roller 3b. However, once the bottom end of the first rod 31a1 approaches the top end of the second rod 31a2 to within a certain distance, ascent of the first rod 31a1 with respect to the second rod 31a2 stops, and the first rod 31a1 together with the second rod 31a2 ascend with respect to the third rod 31a3. Once the bottom end of the second rod 31a2 approaches the top end of the third rod 31a3 to within a certain distance, the ascent of the second rod 31a2 with respect to the third rod 31a3 is configured to stop. The support rod 131a is thereby configured to extend/retract like a multi-segmented antenna without the first rod 31a1 falling out of the second rod 31a2 or the second rod 31a2 falling out of the third rod 31a3 when the support rod 131a is extended. In the embodiment shown in FIG. 4, the support rod is comprised of first to third rods, but the present invention is not limited thereto. A support rod may be comprised of first and second rods or four or more rods.

Since the support rod 131a itself is fixed without moving with respect to the aerial vehicle body in such a moving mechanism 131 comprising the support rod 131a and rod extending/retracting means 131b, interference with other configurations of a device is suppressed. Thus, the moving mechanism can have a simple configuration.

The aerial vehicle 100 in Embodiment 1 and the aerial vehicle 101 in Modified Example 1 thereof described above may comprise a rotation mechanism for rotating the conductive member 120 in addition to the configurations described above. In the following Modification Examples 2 and 3, the aerial vehicle 100 in Embodiment 1 comprising a rotation mechanism for rotating the conductive member 120 (aerial vehicles 102 and 103) is described.

### Modification Example 2 of Embodiment 1

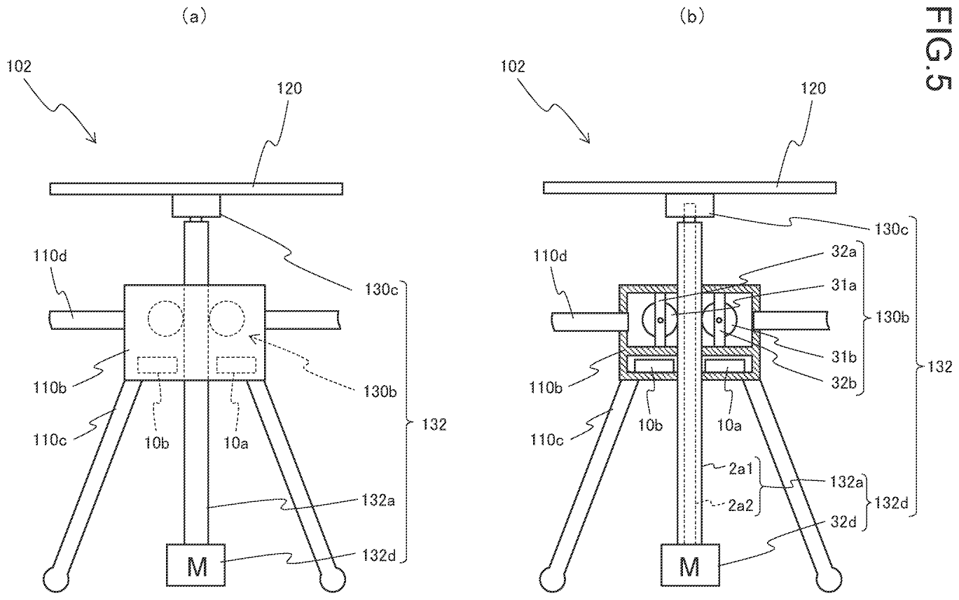

FIG. 5 is a diagram for describing a rotation mechanism for rotating the conductive member 120 of aerial vehicle 102 according to Modified Example 2 of Embodiment 1. FIG. 5(a) is a side view of the aerial vehicle 102, and FIG. 5(b) is a vertical cross-sectional view of the housing 110b shown in FIG. 5(a). A specific configuration of a rotation mechanism 132d for rotating a conductive member is disclosed.

The aerial vehicle 102 according to Modification Example 2 of Embodiment 1 comprises a support rod 132a comprising a rotation shaft 2a2 and a rotation motor 32d for rotating the rotation shaft 2a2 in place of the support rod 130a of the aerial vehicle 100 in Embodiment 1. The rotation mechanism 132d for rotating the conductive member 120 is comprised of the support rod 132a and the rotation motor 32d by supporting the conductive member 120 substantially at the tip of the rotation shaft 2a2. The other configurations are identical to those in the aerial vehicle 100 in Embodiment 1.

Specifically, the support rod 132a has a tubular support rod body 2a1 and a stick-like rotation shaft 2a2 housed within the support rod body 2a1. The rotation shaft 2a2 is rotatably retained within the support rod body 2a1. The top end of the rotation shaft 2a2 protrudes out from the support rod body 2a1 and is coupled to the conductive member 120 with the coupling member 130c.

The bottom end of the support rod body 2a1 is attached to the rotation motor 32d. The rotation axis of the rotation motor 32d is coupled to the bottom end of the stick-like rotation shaft 2a2 housed within the support rod body 2a1. The rotation motor 32d is shaft rotation means for rotating the rotation shaft 2a2.

Thus, in Modification Example 2 of Embodiment 1, the rotation mechanism 132d for rotating the conductive member 120 is comprised of the support rod 132a and the shaft rotation means 132d.

Since the moving mechanism 132 in the aerial vehicle 102 according to Modification Example 2 of Embodiment 1 with such a configuration comprises the rotation mechanism 132d for rotating the conductive member 120 in addition to the rod moving means 130b capable of moving the support rod 132a in a distal direction, the conductive member 120 can be contacted with the receptor Lc of the wind turbine blade Wb in a state where the conductive member 120 is rotated. Rotating a conductive member in such a manner can remove any insulating coating, waste, or rust adhering to the surface of the receptor Lc of the wind turbine blade Wb by the rotating conductive member 120, and can further ensure inspection of electrical connection via a down conductor of the conductive member 120 and the receptor Lc of the wind turbine blade Wb.

Modification Example 2 of Embodiment 1 discloses the rotation mechanism 132d for rotating the conductive member 120, wherein the conductive member 120 is coupled to one end of the rotation shaft 2a2 rotatably housed inside the support rod body 2a1, and a rotation axis of the rotation motor 32d is coupled to the other end of the rotation shaft 2a2, but the configuration of the rotation mechanism 132d of the invention is not limited thereto. For example, the configuration may rotate the rod moving means 130b of Embodiment 1, or may comprise a rotation mechanism in the conductive member 120 itself.

Furthermore, Embodiment 1 and Modification Examples 1 and 2 thereof disclose the aerial vehicles 100 to 103 wherein the posture of the conductive member 120 with respect to a support rod is fixed, but aerial vehicles are not limited to those in which the posture of a conductive member with respect to a support rod is fixed. An aerial vehicle may be an aerial vehicle wherein the posture of a conductive member with respect to a support rod (rotation direction or rotation angle with respect to the support rod) can be changed in any manner. An aerial vehicle with such a configuration is described hereinafter as Embodiment 2.

### Embodiment 2

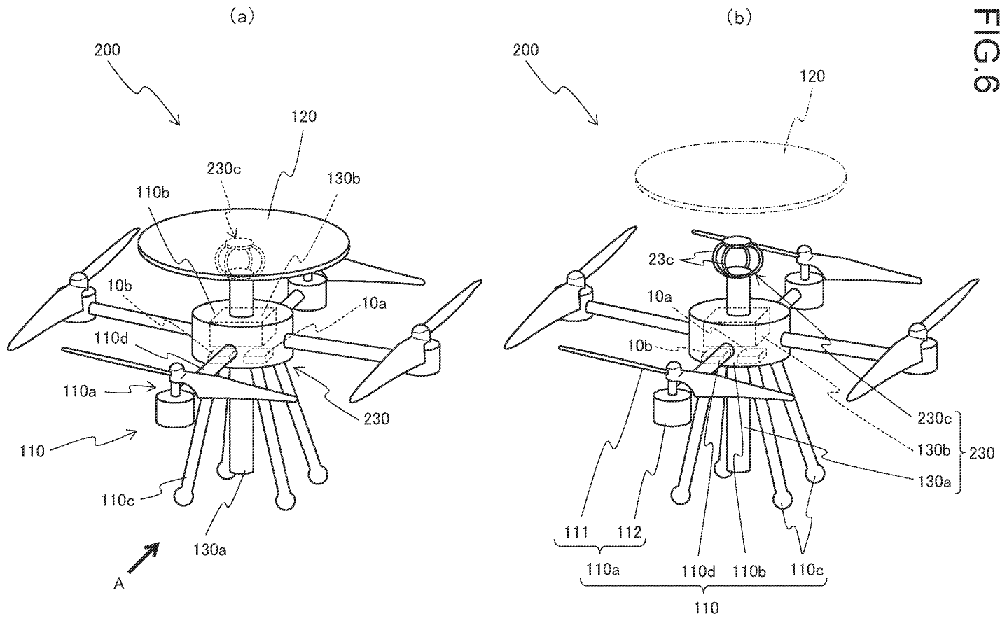

FIG. 6 is a perspective view for describing aerial vehicle 200 according to Embodiment 2 of the invention. FIG. 6(a) shows the outer appearance of the aerial vehicle 200, and FIG. 6(b) shows the structure of coupling member 230c by separating the conductive member 120 from the aerial vehicle 200.

The aerial vehicle 200 of Embodiment 2 is different only in terms of the following: the coupling member 130c of the aerial vehicle 100 of Embodiment 1 is coupled so that the posture of the conductive member 120 with respect to the moving mechanism 130 is fixed, whereas the coupling member 230c is coupled so that the posture of the conductive member 120 with respect to the moving mechanism 230 can be changed in any manner.

Specifically, the coupling member 230c comprises a plurality of flexible members 23 consisting of an elastic metal wire, and the plurality of flexible members 23 are disposed with a given angular interval axially about the support rod 130a. In this regard, the four flexible members 23 are disposed axially about the support rod 130a at an angular interval of 90°. However, the four flexible members 23 are not limited to a metal wire member and may be a coil spring, leaf spring, or elastic resin or rubber, as long as they can support the conductive member 120 at a given posture (e.g., horizontally) and deform when the conductive member 120 abuts a receptor of a wind turbine blade.

A method of inspecting electrical connectivity of a receptor of a wind turbine blade, etc. by using the aerial vehicle 200 with such a configuration is now described.

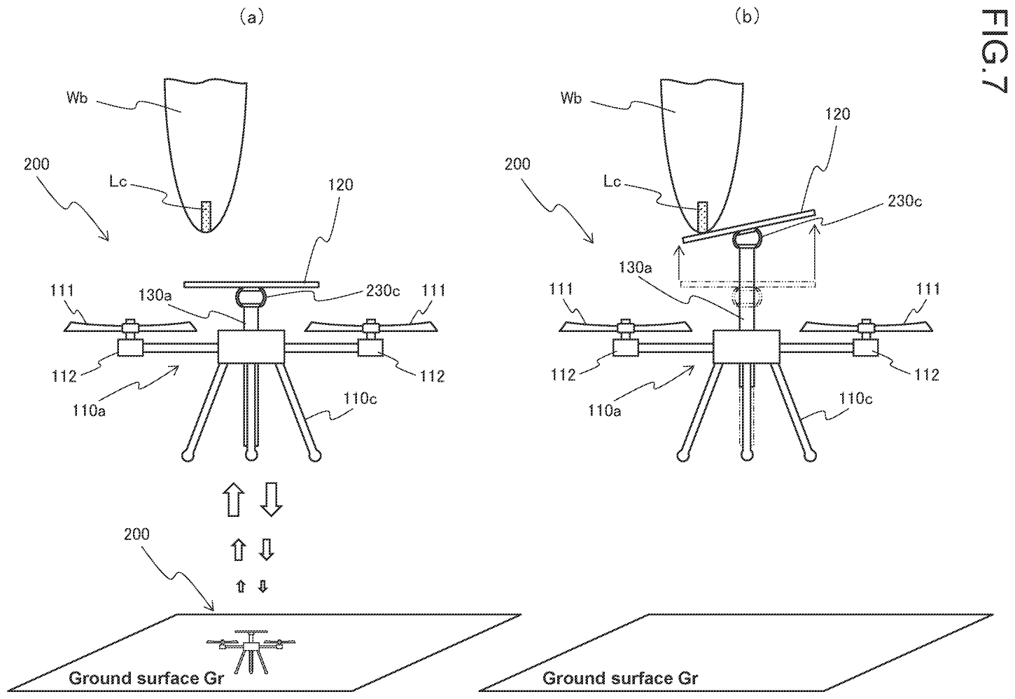

FIG. 7 is a diagram for describing a method of inspecting electrical connectivity of a receptor, etc. by using the aerial vehicle 200 shown in FIG. 6. FIG. 7(a) shows the ascending and descending motions of the aerial vehicle 200 in FIG. 7, and FIG. 7(b) shows an upward movement of the conductive member 120 of the aerial vehicle 200 in FIG. 6.

Electric connectivity inspection on a structure such as a wind turbine blade of a wind turbine by using the aerial vehicle 200 of Embodiment 2 is also conducted in the same manner as the electric connectivity inspection using the aerial vehicle 100 of Embodiment 1.

Specifically, as shown in FIG. 7(a), the aerial vehicle 200 is moved to a position below the conductor Lc of the wind turbine blade Wb while maintaining the conductive member 120 at a proximal position with respect to the aerial vehicle body 110 (first step).

Next, as shown in FIG. 7(b), the conductive member 120 is contacted with the conductor Lc of the structure Wb by moving the conductive member 120 to a distal position with respect to the aerial vehicle body 110 to conduct electric connectivity inspection (second step).

The aerial vehicle 200 can avoid losing the balance while maintaining the contact of a conductive member with the conductor Lc by changing the posture of the conductive member 120 with respect to the support rod 131a (rotation direction or rotation angle with respect to the support rod) in accordance with the force of wind as shown in FIG. 7(b), even if a point of contact where the conductive member 120 contacts the conductor Lc of the structure Wb becomes offset from the center of the aerial vehicle 100 due to a force of a wind, etc. in the aerial vehicle 200 of Embodiment 2.

Subsequently, the aerial vehicle 200 is descended and landed on the group surface Gr while the conductive member 120 is returned to the proximal position with respect to the aerial vehicle body 110 and the aerial vehicle 200 is stabilized, in the same manner as the electric connectivity inspection using the aerial vehicle 100 of Embodiment 1 (see FIG. 7(a)).

In the aerial vehicle 200 of Embodiment 2 with such a configuration, the conductive member 120 is coupled to the support rod 130a in a manner that the posture (rotation direction or rotation angle with respect to the support rod) can be changed with the coupling member 230c comprising the plurality of flexible members 23 in addition to the configuration of the aerial vehicle 100 of Embodiment 1. Thus, the aerial vehicle 200 can avoid losing balance while maintaining the contact of the conductive member 120 with a receptor by changing the posture of the conductive member 120 in accordance with a force of a wind, etc. when the conductive 120 abuts a receptor of a wind turbine blade at a position offset from the center of the aerial vehicle 200 due to the force, in addition to the effect of the aerial vehicle 100 of Embodiment 1.

While the coupling member 230c having a plurality of flexible members 23 was used in the aerial vehicle 200 of Embodiment 2, a coupling member is not limited to those with such a structure. For example, a universal joint or a ball joint may be used as a coupling member.

### Embodiment 3

A method of inspecting electric connectivity of a receptor of a wind turbine blade, etc. by using the aerial vehicle 300 of Embodiment 3 is now described.

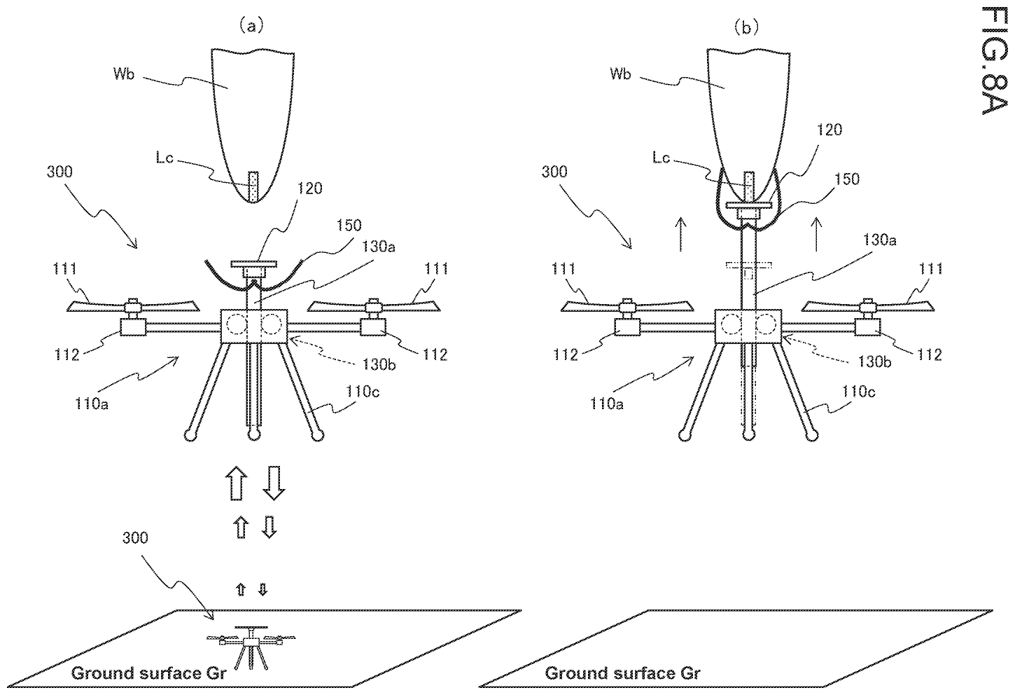

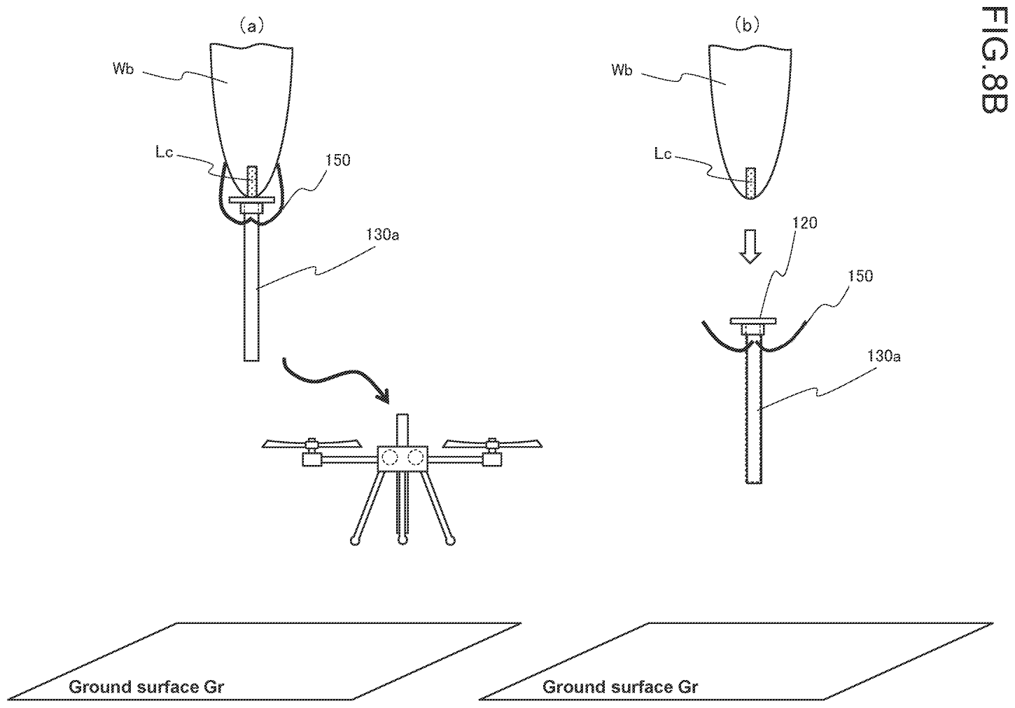

FIG. 8A is a diagram for describing a method of inspecting electrical connectivity of a receptor, etc. by using aerial vehicle 300 according to Embodiment 3 of the invention. FIG. 8A(a) shows ascending and descending motions of the aerial vehicle 300, and FIG. 8A(b) shows an operation of fixing the conductive member 120 of the aerial vehicle 300 to a receptor. FIG. 8B(a) shows an operation of releasing the aerial vehicle 300 from a wind turbine blade while a conductive member is still fixed to a receptor, and FIG. 8B(b) shows an operation of disengaging fixation of a conductive member to a receptor and releasing the conductive member and a support rod from a wind turbine blade after electrical connectivity inspection.

A method of conducting electric connectivity inspection on a structure such as a wind turbine blade of a wind turbine by using the aerial vehicle 300 shown in FIG. 8A comprises at least the following first to fourth steps.

### First Step

The first step is the same as the first step for the aerial vehicle 100 of Embodiment 1 shown in FIG. 3.

### Second Step

The second step is the same as the second step for the aerial vehicle 100 of Embodiment 1 shown in FIG. 3, until the aerial vehicle 300 floating at a position in the vicinity of the lower side of the receptor Lc abuts the receptor Lc of the wind turbine blade Wb during the move of the conductive member 120 from a proximal position to a distal position.

### Third Step

As shown in FIG. 8A(b), the conductive member 120 is fixed to the receptor Lc by attaching the support rod 130a to the wind turbine blade Wb through actuation of a clamp (fixing means) 150 comprising a linking mechanism equipped by the support rod 130a while the conductive member 120 abuts the receptor Lc of the wind turbine blade Wb.

### Fourth Step

As shown in FIG. 8B(c), the conductive member 120 is fixed to the receptor Lc by the fixing means 150, and then the aerial vehicle 300 is released from the wind turbine blade Wb by disengaging the connection of the support rod 130a to the aerial vehicle 300. The aerial vehicle 300 can avoid colliding with the wind turbine blade Wb or wind turbine due to the effect of a strong wind, etc. by releasing the aerial vehicle 300 from the wind turbine blade Wb.

### Fifth Step

The conductive member 120 is electrically connected with the receptor Lc of the wind turbine blade Wb while the conductive member 120 is fixed to the wind turbine blade Wb, whereby the receptor Lc of the wind turbine blade Wb is connected to a measurement device on the ground via the conductive member 120 of the aerial vehicle 100 and measurement cable (not shown), and the quality of electrical connection via a down conductor between a receptor and ground is determined with the measurement device on the ground.

### Sixth Step

After electrical connectivity inspection, an instruction signal in a form of a wireless signal, etc. from the aerial vehicle 300, etc. is transmitted to disengage fixture of the conductive member 120 to the receptor Lc by the fixing means 150, whereby the conductive member 120 and the support rod 130a are released (natural drop) from the wind turbine blade Wb, as shown in FIG. 8B(b).

In this manner, the aerial vehicle 300 of Embodiment 3 was configured so that the aerial vehicle 300 is released from the wind turbine blade Wb when the conductive member 120 contacts with and is fixed to the receptor Lc. Thus, the risk of the aerial vehicle body 110 colliding with the wind turbine blade Wb can be averted. For this reason, the aerial vehicle 300 of the invention enables safe and simple electrical connectivity inspection on the conductor Lc of the wind turbine blade Wb. While the embodiment shown in FIG. 8 describes a case where the conductive member 120 and the support rod 130a are released from the wind turbine blade Wb, the embodiment may be configured so that the conductive member 120 comprises the fixing means 150, and only the conductive member 120 is released from the wind turbine blade Wb.

As disclosed above, the present invention is exemplified by the use of its preferred embodiments. However, the present invention should not be interpreted to be limited to such embodiments. It is understood that the scope of the present invention should be interpreted based solely on the claims. It is understood that an equivalent scope can be practiced by those skilled in the art from the specific descriptions in the preferred embodiments of the invention based on the descriptions of the present invention and common general knowledge. It is understood that any references cited herein should be incorporated herein by reference in the same manner as the contents are specifically described herein.

### INDUSTRIAL APPLICABILITY

The present invention is useful in the field of aerial vehicles and electrical connectivity inspecting methods as an invention that can obtain an aerial vehicle which enables safe and simple electrical connectivity inspection on a structure and an electrical connectivity inspecting method using such an aerial vehicle.

### REFERENCE SIGNS LIST

100 to 103, 200, 201, 300 Aerial vehicle
110 Aerial vehicle body
120 Conductive member
130 to 133, 230, 231 Moving mechanism
130a, 131a, 132a Support rod
130b Rod moving means
130c, 230c, 231c Coupling member
131b Rod extending/retracting means
132d, 133d Rod rotation means (rotation mechanism)
Lc Lightning conductor
Wb Wind turbine blade

1. An aerial vehicle, comprising:
an aerial vehicle body;
a conductive member for contacting a conductor of a structure; and
a moving mechanism capable of moving the conductive member between a distal position and a proximal position of the aerial vehicle body.

2. The aerial vehicle of claim 1, wherein the moving mechanism comprises:
a support rod for supporting the conductive member; and
rod moving means capable of moving the support rod to a distal direction.

3. The aerial vehicle of claim 1, wherein the moving mechanism comprises:
an extendable/retractable support rod for supporting the conductive member; and
rod extending/retracting means for extending/retracting the support rod.

4. The aerial vehicle of claim 3, wherein the extendable/retractable support rod comprises at least:
a first rod coupled to the conductive member; and
a second rod for protrudably and embeddably housing the first rod.

5. The aerial vehicle of claim 2, wherein the conductive member and the support rod are coupled with a coupling member so that a posture of the conductive member can be changed in any manner.

6. The aerial vehicle of claim 5, wherein
the coupling member comprises a plurality of flexible members, and
the plurality of flexible members are disposed with a given angular interval axially about the support rod.

7. The aerial vehicle of claim 5, wherein the coupling member is a universal joint.

8. The aerial vehicle of claim 1, wherein the aerial vehicle further comprises a rotation mechanism for rotating the conductive member.

9. The aerial vehicle of claim 1, wherein the conductive member comprises at least one of a metal wire netting, a checker plate, a metal scrubber, a metal brush, conductive rubber, conductive sponge, a conductive wire, conductive grease, conductive oil, and a perforated board.

10. The aerial vehicle of claim 2, wherein the support rod or the conductive member further comprises fixing means for fixing the conductive member to the conductor.

11. The aerial vehicle of claim 1, wherein the moving mechanism moves a conductive member in a substantially vertical direction of the aerial vehicle body, and the distal position is a position in an upward direction of the substantially vertical direction with respect to the proximal position.

12. A method of conducting electrical connectivity inspection on the structure by using the aerial vehicle of claim 1, comprising:
moving the aerial vehicle to a position below a conductor of the structure while the conductive member is at the proximal position; and
contacting the conductive member with the conductor of the structure by moving the conductive member to the distal position to conduct electrical connectivity inspection.

13. The method of claim 12, further comprising:
fixing the conductive member to the conductor;
detaching the conductive member from the aerial vehicle, while the conductive member is fixed to the conductor, to release the aerial vehicle from the structure; and
disengaging fixation of the conductive member to the conductor as of completion of the electrical connectivity inspection to release the conductive member from the structure.

14. The method of claim 12, wherein the conductor of the structure is a receptor provided at a tip of a wind turbine blade.
